(19) United States
(12) Patent Application Publication
(10) Pub. No.: US 2026/0096016 A1
(43) Pub. Date: Apr. 2, 2026

(54) CIRCUIT BOARD

(71) Applicant: CHIPBOND TECHNOLOGY CORPORATION, Hsinchu (TW)

(72) Inventors: Pei-Yi Wang, Kaohsiung City (TW); Shih-Chuan Lee, Kaohsiung City (TW); Chien-Hung Chiu, Kaohsiung City (TW)

(21) Appl. No.: 19/005,918

(22) Filed: Dec. 30, 2024

(30) Foreign Application Priority Data
Sep. 27, 2024 (TW) 113137172

(51) Int. Cl. H05K 1/02

(52) U.S. Cl. CPC H05K 1/0271; H05K 1/0298

(57) ABSTRACT

A circuit board includes a substrate, a circuit layer, a solder resist layer, and at least one moisture barrier layer. The circuit layer is provided on the substrate and covered by the solder resist layer. Inner and outer leads of the circuit layer are not covered by the solder resist layer. The moisture barrier layer covers the solder resist layer such that the circuit layer and the solder resist layer are located between the substrate and the moisture barrier layer. The moisture barrier layer is provided to block liquid or moisture such that liquid or moisture cannot permeate to the solder resist layer and the circuit layer to cause corrosion or oxidation of the circuit layer.

### CROSS-REFERENCE TO RELATED APPLICATIONS

This application claims priority to R.O.C Patent Application No. 113137172 filed Sep. 27, 2024, the disclosure of which is hereby incorporated by reference in its entirety.

### FIELD OF THE INVENTION

This invention relates to a circuit board, and more particularly to a circuit board that protects a circuit layer from oxidation or corrosion.

### BACKGROUND OF THE INVENTION

Referring to FIG. 1, a circuit layer 12 is formed on a substrate 11 and covered by a solder resist layer 13 in a conventional circuit board 10. During manufacture, transport, or storage of the circuit board 10, liquid adhered to the solder resist layer 13 or moisture in the environment may permeate to the circuit layer 12 via the solder resist layer 13 to cause oxidation and short circuit of the circuit layer 12. Moreover, if there are corrosive elements (e.g., Chlorine) in liquid or moisture, the corrosive elements may permeate to the solder resist layer 13 and the circuit layer 12 with liquid or moisture, and the circuit layer 12 may be corroded by the corrosive elements to cause break circuit and reduce the reliability of the circuit board 10.

### SUMMARY OF THE INVENTION

One object of the present invention is to provide a circuit board that can prevent liquid or moisture from permeating a solder resist layer and a circuit layer using at least one moisture barrier layer to protect the circuit layer from oxidation or corrosion.

A circuit board of the present invention includes a substrate, a circuit layer, a solder resist layer, and a first moisture barrier layer. The circuit layer is provided on the substrate and includes inner leads and outer leads. The solder resist layer, except the inner and outer leads, covers the circuit layer. The first moisture barrier layer covers the solder resist layer in such a way that the circuit layer and the solder resist layer are located between the substrate and the first moisture barrier layer. The first moisture barrier layer's water vapor transmission rate (WVTR) is less than or equal to 1×10⁻² g/m²·day.

The first moisture barrier layer blocks liquid or moisture so that liquid, moisture, or corrosive elements in the liquid or moisture cannot permeate into the solder resist layer and the circuit layer. The circuit layer will not be oxidized or corroded to lower the reliability of the circuit board.

### BRIEF DESCRIPTION OF DRAWINGS

FIG. 1 is a cross-section view diagram illustrating a conventional circuit board.

FIG. 2 is a top-view diagram illustrating a circuit board in accordance with one embodiment of the present invention.

FIG. 3 is a cross-section view diagram illustrating a circuit board in accordance with one embodiment of the present invention.

FIG. 4 is a cross-section view diagram illustrating a circuit board in accordance with another embodiment of the present invention.

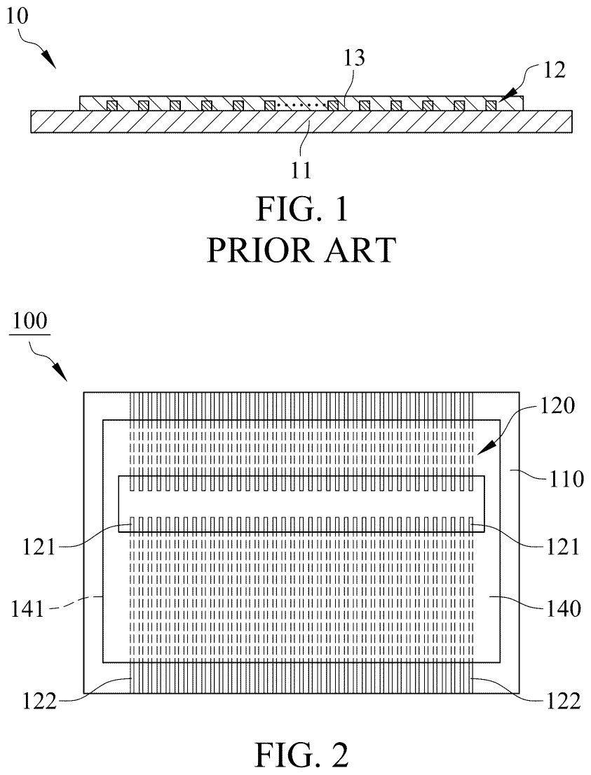

### DETAILED DESCRIPTION OF THE INVENTION

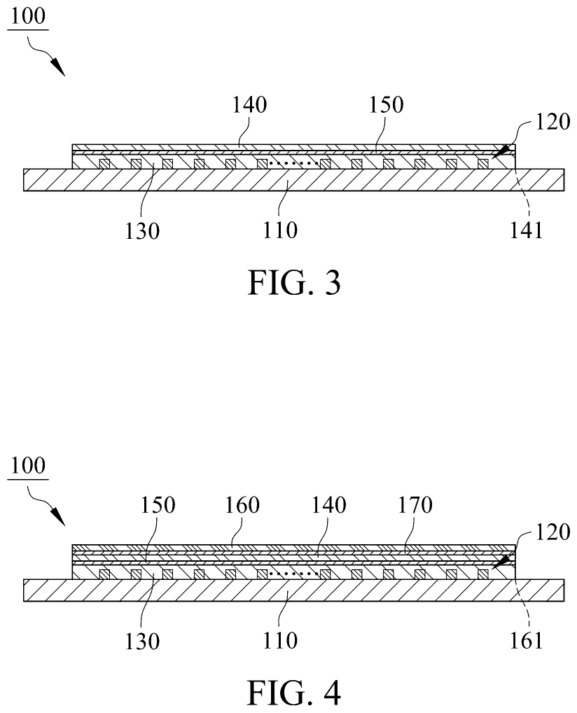

With reference to FIGS. 2 and 3, a circuit board 100, in accordance with one embodiment of the present invention, includes a substrate 110, a circuit layer 120, a solder resist layer 130, and a first moisture barrier layer 140. The circuit layer 120 is provided on substrate 110 and includes inner leads 121 and outer leads 122. The inner leads 121 are provided to be electrically connected to a chip, and the outer leads 122 are provided to be electrically connected to another electronic component, e.g., a display panel. The solder resist layer 130 covers the circuit layer 120, except the inner leads 121 and the outer leads 122.

With reference to FIGS. 2 and 3, the first moisture barrier layer 140 covers the solder resist layer 130 such that the circuit layer 120 and the solder resist layer 130 are located between the substrate 110 and the first moisture barrier layer 140. The water vapor transmission rate (WVTR) of the first moisture barrier layer 140 is less than or equal to 1×10⁻² g/m²·day. The first moisture barrier layer 140 has a thickness of not greater than 50 μm, and it can be made of copper, aluminum, polyvinylidene difluoride (PVDF), or polytetrafluoroethylene (PTFE). Preferably, the WVTR of the first moisture barrier layer 140 is 0.0 g/m²·day.

With reference to FIGS. 2 and 3, the solder resist layer 130 is located on an area 141 defined by the projection of the outer edges of the first moisture barrier layer 140 onto the substrate 110, and the solder resist layer 130 is covered by the first moisture barrier layer 140 completely.

Referring to FIG. 3, the circuit board 100 further includes a second moisture barrier layer 150 in this embodiment. The second moisture barrier layer 150 is located between the first moisture barrier layer 140 and the solder resist layer 130, and the first moisture barrier layer 140 is connected to the solder resist layer 130 via the second moisture barrier layer 150. The second moisture barrier layer 150 has a WVTR of less than or equal to 10 g/m²·day and has a thickness not greater than 80 μm. Preferably, the second moisture barrier layer 150 is adhesive and can be made of a pressure-sensitive material, such as acrylic pressure-sensitive adhesive or epoxy resin-based pressure-sensitive adhesive.

With reference to FIG. 4, in another embodiment, the circuit board 100 further includes a third moisture barrier layer 160 which covers the first moisture barrier layer 140. The WVTR of the third moisture barrier layer 160 is not greater than 0.6 g/m²·day, and the thickness of the third moisture barrier layer 160 is not greater than 50 μm. The third moisture barrier layer 160 can be made of a moisture-proof material, e.g., polyimide (PI) or polyethylene terephthalate (PET).

With reference to FIG. 4, the first moisture barrier layer 140 is located in an area 161 defined by the projection of the outer edges of the third moisture barrier layer 160 onto the substrate 110, and the first moisture barrier layer 140 is entirely covered by the third moisture barrier layer 160.

With reference to FIG. 4, preferably, the circuit board 100 further includes an adhesive layer 170. The adhesive layer 170 is provided to adhere the third moisture barrier layer 160 to the first moisture barrier layer 140 so that the first moisture barrier layer 140 and the third moisture barrier layer 160 can be connected as one piece. The adhesive layer 170 has a WVTR of less than or equal to 10 g/m²·day and has a thickness of less than or equal to 80 μm.

With reference to FIG. 3, the first moisture barrier layer 140 or the first and second moisture barrier layers 140 and 150 are provided to block liquid or moisture on the first moisture barrier layer 140 to prevent liquid, moisture or corrosive elements (e.g. Chlorine) in liquid or moisture from permeating to the solder resist layer 130 and the circuit layer 120. Thus, oxidation or corrosion will not happen to the circuit layer 120 to lower the reliability of the circuit board 100.

With reference to FIG. 4, the third moisture barrier layer 160, the first moisture barrier layer 140, and the second moisture barrier layer 150 can block liquid or moisture on the third moisture barrier layer 160 to prevent liquid, moisture, or corrosive elements (e.g., Chlorine) in liquid or moisture from permeating to the solder resist layer 130 and the circuit layer 120. As a result, the circuit layer 120 is protected from oxidation or corrosion to ensure the reliability of the circuit board 100.

While this invention has been particularly illustrated and described in detail with respect to the preferred embodiments thereof, it will be clearly understood by those skilled in the art that is not limited to the specific features shown and described and various modified and changes in form and details may be made without departing from the scope of the claims.

1. A circuit board comprising:
a substrate;
a circuit layer provided on the substrate and including a plurality of inner leads and a plurality of outer leads;
a solder resist layer covering the circuit layer, the plurality of inner and outer leads are not covered by the solder resist layer; and
a first moisture barrier layer covering the solder resist layer, the circuit layer and the solder resist layer are located between the substrate and the first moisture barrier layer, wherein a water vapor transmission rate of the first moisture barrier layer is less than or equal to 1×10⁻² g/m²·day.

2. The circuit board in accordance with claim 1, wherein the solder resist layer is located on an area defined by a projection of the first moisture barrier layer onto the substrate, and the solder resist layer is covered by the first moisture barrier layer completely.

3. The circuit board in accordance with claim 1, wherein a thickness of the first moisture barrier layer is less than or equal to 50 μm.

4. The circuit board in accordance with claim 1 further comprising a second moisture barrier layer, wherein the first moisture barrier layer is connected to the solder resist layer via the second moisture barrier layer, and a water vapor transmission rate of the second moisture barrier layer is less than or equal to 10 g/m²·day.

5. The circuit board in accordance with claim 4, wherein the second moisture barrier layer is adhesive.

6. The circuit board in accordance with claim 5, wherein a thickness of the second moisture barrier layer is less than or equal to 80 μm.

7. The circuit board in accordance with claim 4 further comprising a third moisture barrier layer covering the first moisture barrier layer, wherein a water vapor transmission rate of the third moisture barrier layer is less than or equal to 0.6 g/m²·day.

8. The circuit board in accordance with claim 7, wherein the first moisture barrier layer is located on an area defined by a projection of the third moisture barrier layer onto the substrate, and the first moisture barrier layer is covered by the third moisture barrier layer completely.

9. The circuit board in accordance with claim 7, wherein a thickness of the third moisture barrier layer is less than or equal to 50 μm.

10. The circuit board in accordance with claim 7 further comprising an adhesive layer, wherein the third moisture barrier layer is adhered to the first moisture barrier layer by the adhesive layer.

11. The circuit board in accordance with claim 10, wherein a water vapor transmission rate of the adhesive layer is less than or equal to 10 g/m²·day.

12. The circuit board in accordance with claim 11, wherein a thickness of the adhesive layer is less than or equal to 80 μm.

13. The circuit board in accordance with claim 1 further comprising a third moisture barrier layer covering the first moisture barrier layer, wherein a water vapor transmission rate of the third moisture barrier layer is less than or equal to 0.6 g/m²·day.

14. The circuit board in accordance with claim 13, wherein the first moisture barrier layer is located on an area defined by a projection of the third moisture barrier layer onto the substrate, and the first moisture barrier layer is covered by the third moisture barrier layer completely.

15. The circuit board in accordance with claim 13, wherein a thickness of the third moisture barrier layer is less than or equal to 50 μm.

16. The circuit board in accordance with claim 13 further comprising an adhesive layer, wherein the third moisture barrier layer is adhered to the first moisture barrier layer by the adhesive layer.

17. The circuit board in accordance with claim 16, wherein a water vapor transmission rate of the adhesive layer is less than or equal to 10 g/m²·day.

18. The circuit board in accordance with claim 17, wherein a thickness of the adhesive layer is less than or equal to 80 μm.
